(19) United States
(12) Patent Application Publication
(10) Pub. No.: US 2024/0222381 A1
(43) Pub. Date: Jul. 4, 2024

(54) ELECTRONIC DEVICE

(71) Applicant: WUHAN CHINA STAR OPTOELECTRONICS TECHNOLOGY CO., LTD., Wuhan, Hubei (CN)

(72) Inventors: Wenqiang Yu, Wuhan, Hubei (CN); Chao Wang, Wuhan, Hubei (CN)

(73) Assignee: WUHAN CHINA STAR OPTOELECTRONICS TECHNOLOGY CO., LTD., Wuhan, Hubei (CN)

(21) Appl. No.: 17/758,218

(22) PCT Filed: May 23, 2022
(86) PCT No.: PCT/CN2022/094365

§ 371 Date: Nov. 16, 2023

(30) Foreign Application Priority Data
May 12, 2022 (CN) 202210516996.6

(51) Int. Cl. H01L 27/12

(52) U.S. Cl. CPC H01L 27/124

(57) ABSTRACT

An electronic device including a first metal layer and a second metal layer is provided. The first metal layer and the second metal layer are arranged in different layers, wherein the first metal layer includes source electrodes and data lines, and the second metal layer includes drain electrodes. Further, the first metal layer includes data line groups, and each data line group includes a plurality of the data lines, wherein a distance between any two adjacent data line groups is less than a distance between any two adjacent data lines in any data line group.

### FIELD OF INVENTION

The present application relates to a field of display technology, particularly relates to an electronic device.

### BACKGROUND OF INVENTION

In current electronic devices, especially in virtual reality (VR) devices, due to a limitation of resolution, viewing effect is seriously affected, and the user may feel dizzy.

Currently, in manufacture of an array substrate of electronic devices, source electrodes, drain electrodes, and data lines of thin film transistors need to be arranged in a same metal layer. However, exposure equipment of current panel factory has capability limitations in terms of line width and line pitch of circuits. In addition, a certain distance needs to be reserved between the source electrode, the drain electrode, and the data line to reserve space and reduce parasitic capacitance. Therefore, it is difficult to reserve extra space on a side of the array substrate to improve resolution.

### Technical Problem

An embodiment of the present application provides an electronic device, which can save space required for wiring and improve the resolution of the electronic device.

### SUMMARY OF INVENTION

An embodiment of the present application provides an electronic device, which includes: a first substrate; a semiconductor layer disposed on a side of the first substrate, wherein the semiconductor layer includes active parts, and each active part includes a source contact sub-portion, a drain contact sub-portion, and a channel sub-portion positioned between the source contact sub-portion and the drain contact sub-portion; a first metal layer disposed on a side of the semiconductor layer away from the first substrate and including source electrodes and data lines, wherein one end of one of the source electrodes is electrically connected to a respective one of the data lines, and another end of the source electrode is electrically connected to the source contact sub-portion of the active part; a second metal layer disposed on the side of the semiconductor layer away from the first substrate and is positioned in a different layer from the first metal layer, wherein the second metal layer includes drain electrodes, one of the drain electrodes is electrically connected to the drain contact sub-portion of one of the active parts; wherein the first metal layer includes data line groups, each data line group includes a plurality of the data lines, and wherein a distance between any two adjacent data line groups is less than a distance between any two adjacent data lines in any of the data line groups.

In an embodiment of the present application, the second metal layer is disposed on a side of the first metal layer away from the semiconductor layer, and the electronic device further includes a spacer layer disposed between the first metal layer and the second metal layer.

In an embodiment of the present application, the data lines are arranged along a first direction and extend along a second direction, the first direction is different from the second direction, and wherein an orthographic projection of the drain electrode on the first substrate is positioned between orthographic projections of two adjacent data lines in one of the data line groups on the first substrate.

In an embodiment of the present application, a width of the drain electrode along the first direction is greater than or equal to 2 μm.

In an embodiment of the present application, a width of the drain electrode along the first direction is equal to a spacing between the two adjacent data lines in the data line group.

In an embodiment of the present application, a width of the drain electrode along the first direction is less than a spacing between the two adjacent data lines in the data line group.

In an embodiment of the present application, the electronic device further includes pixel areas, wherein one of the pixel areas corresponds to one of the data line groups, and each pixel area includes one of first sub-pixel areas, one of second sub-pixel areas adjacent to the first sub-pixel area along the first direction, and one of third sub-pixel areas adjacent to the first sub-pixel area along the second direction; and wherein each data line group includes a first data line, a second data line, and a third data line, the first sub-pixel area and the third sub-pixel area in the pixel area are positioned between the first data line and the second data line in the data line group, and the second sub-pixel area in the pixel area is positioned between the second data line and the third data line in the data line group.

In an embodiment of the present application, the first data line in one of the data line groups is adjacent to the third data line in an adjacent one of the data line groups, and wherein a distance between two adjacent first data line and third data line in two adjacent data line groups is less than a distance between the first data line and the second data line in the data line group, or less than a distance between the second data line and the third data line in the data line group.

In an embodiment of the present application, the electronic device further includes a second substrate disposed on a side of the first metal layer and the second metal layer away from the first substrate, and a color resist layer disposed on a side of the second substrate close to the first substrate, wherein the color resist layer includes first color resist blocks, second color resist blocks, and third color resist blocks disposed corresponding to each of the pixel areas; and wherein one of the first color resist blocks is correspondingly disposed in one of the first sub-pixel areas and partially overlaps with adjacent first data line and second data line, one of the second color resist blocks is correspondingly disposed in one of the second sub-pixel areas and partially overlaps with adjacent second data line and third data line, and one of the third color resist blocks is correspondingly disposed in one of the third sub-pixel areas and partially overlaps with adjacent first data line and second data line.

In an embodiment of the present application, wherein a length of an overlapping portion of the first color resist block and the first data line along the first direction is equal to a width of the first data line along the first direction, and a length of an overlapping portion of the first color resist block and the second data line along the first direction is less than a width of the second data line along the first direction; wherein a length of an overlapping portion of the second color resist block and the second data line along the first direction is less than a width of the second data line along the first direction, and a length of an overlapping portion of the second color resist block and the third data line along the first direction is equal to a width of the third data line along the first direction; and wherein a length of an overlapping portion of the third color resist block and the first data line along the first direction is equal to a width of the first data line along the first direction, and a length of an overlapping portion of the third color resist block and the second data line along the first direction is less than or equal to a width of the second data line along the first direction.

In an embodiment of the present application, each pixel area further includes a fourth sub-pixel area adjacent to the third sub-pixel area in the first direction and adjacent to the second sub-pixel area in the second direction, and the third color resist block is disposed in the third sub-pixel area and partially extends to the fourth sub-pixel area.

In an embodiment of the present application, each source electrode is connected to a respective one of the data lines and is connected to a respective one of the drain electrodes through a respective one of the active parts, wherein the drain electrodes include a first drain electrode corresponding to the first data line, and in each pixel area, the first drain electrode is disposed in the fourth sub-pixel area.

In an embodiment of the present application, the drain electrodes further include a second drain corresponding to the second data line, the source electrodes include a third source electrode corresponding to the third data line, and the first drain electrode, the second drain electrode, and the third source electrode are arranged along the first direction and positioned between two adjacent pixel areas along the second direction.

In an embodiment of the present application, the electronic device further includes a third metal layer disposed on a side of the first metal layer and the second metal layer close to the semiconductor layer, and the third metal layer includes scan lines extending along the first direction and arranged along the second direction, each scan line is positioned between two adjacent pixel areas arranged along the second direction, and the first drain electrode, the second drain electrode, and the third source electrode are all positioned on a side of the scan lines away from the first substrate.

In an embodiment of the present application, the electronic device further includes a black matrix layer disposed on the side of the second substrate close to the first substrate, wherein the black matrix layer is arranged around the first sub-pixel area, the second sub-pixel area, and the third sub-pixel area; and wherein an orthographic projection of the scan line on the first substrate, an orthographic projection of the first drain electrode on the first substrate, an orthographic projection of the second drain electrode on the first substrate, and an orthographic projection of the third source electrode on the first substrate are all positioned within a coverage range of an orthographic projection of the black matrix layer on the first substrate.

In an embodiment of the present application, the black matrix layer includes a first sub-portion disposed between the first sub-pixel area and the third sub-pixel area and between two adjacent scan lines and a second sub-portion disposed between two adjacent pixel areas along the second direction, wherein a length of the first sub-portion along the second direction is less than a length of the second sub-portion along the second direction; and wherein an orthographic projection of the scan line on the first substrate, an orthographic projection of the first drain electrode on the first substrate, an orthographic projection of the second drain electrode on the first substrate, and an orthographic projection of the third source electrode on the first substrate are all positioned within a coverage range of an orthographic projection of the second sub-portion on the first substrate.

### Advantages

Compared with prior art, in the present application, the source electrodes and the data lines are arranged in a first metal layer, and the drain electrodes are arranged in a second metal layer, that is, the drain electrodes are arranged in a different layer from the source electrodes and the data lines. Therefore, both the first metal layer and the second metal layer have more space for wiring, which reduces difficulty of a manufacturing process and improves resolution of electronic devices. In addition, each data line group includes a plurality of data lines, and a distance between any two adjacent data line groups is less than a distance between any two adjacent data lines in any data line group, that is, at least the distance between two adjacent data line groups is reduced, more space for wiring can be reserved, and the resolution of the electronic devices can be improved.

### DESCRIPTION OF DRAWINGS

With reference to the accompanying drawings, the technical solutions and other advantages of the present application will be described clearer through the detailed description of specific embodiments of the present application.

FIG. 1 is a schematic structural diagram of a display panel provided by an embodiment of the present application.

FIG. 2 is a schematic diagram of a distribution structure of data lines in a display panel according to an embodiment of the present application.

FIG. 3 is a schematic diagram of a distribution structure of data lines of a conventional display panel.

FIG. 4 is a schematic diagram of a distribution structure of conventional data lines and drain electrodes.

FIG. 5 is a schematic diagram of a distribution structure of a data line and a drain electrode according to an embodiment of the present application.

FIG. 6 is a schematic diagram of another distribution structure of data lines and drain electrodes according to an embodiment of the present application.

FIG. 7 is a schematic top view wiring diagram of a display panel according to an embodiment of the present application.

FIG. 8 is a schematic top view distribution diagram of a pixel area of a display panel according to an embodiment of the present application.

### DETAILED DESCRIPTION OF PREFERRED EMBODIMENTS

The technical solutions in the embodiments of the present application will be clearly described with reference to the accompanying drawings in the embodiments of the present application. Obviously, the embodiments are only a part of the embodiments of the present application, but not all the embodiments. Based on the embodiments in the present application, all other embodiments obtained by one skill in the art without doing creative work fall within the protection scope of the present application.

The following disclosure provides many embodiments or examples for implementing different structures of the present application. To simplify the disclosure of the present application, the components and arrangements of specific examples are described below. Certainly, they are only examples and are not intended to limit the application. Furthermore, this application may repeat reference numerals and/or reference letters in various instances, such repetition for simplicity and clarity and not to represent a relationship between the various embodiments and/or arrangements discussed. In addition, this application provides examples of various specific processes and materials, but one ordinary skill in the art will recognize the application of other processes and/or the use of other materials.

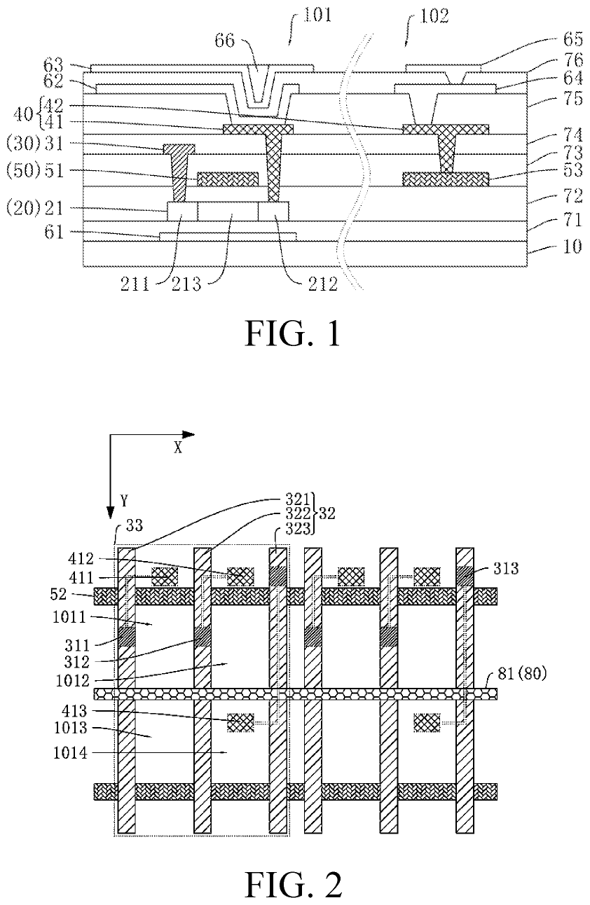

An embodiment of the present application provides an electronic device. Referring to FIG. 1 and FIG. 2, the electronic device includes a first substrate 10, a semiconductor layer 20, a first metal layer 30, and a second metal layer 40.

Wherein, the semiconductor layer 20 is disposed on a side of the first substrate 10 and includes a plurality of active parts 21. Each active part 21 includes a source contact sub-portion 211, a drain contact sub-portion 212, and a channel sub-portion 213 positioned between the source contact sub-portion 211 and the drain contact sub-portion 212. The first metal layer 30 is disposed on a side of the semiconductor layer 20 away from the first substrate 10 and includes a plurality of source electrodes 31 and a plurality of data lines 32. One end of a source electrode 31 is electrically connected to a corresponding data line 32, and another end of the source electrode 31 is electrically connected to a source contact sub-portion 211 of an active part 21. The second metal layer 40 is disposed on the side of the semiconductor layer 20 away from the first substrate 10 and is arranged in a different layer from the first metal layer 30. The second metal layer 40 includes a plurality of drain electrodes 41, wherein a drain electrode 41 is electrically connected to the drain contact sub-portion 212 of an active part 21.

Further, the first metal layer 30 includes a plurality of data line groups 33, and each data line group 33 includes a plurality of data lines 32, wherein the distance between any two adjacent data line groups 33 is less than the distance between any two adjacent data lines 32 in any data line group 33.

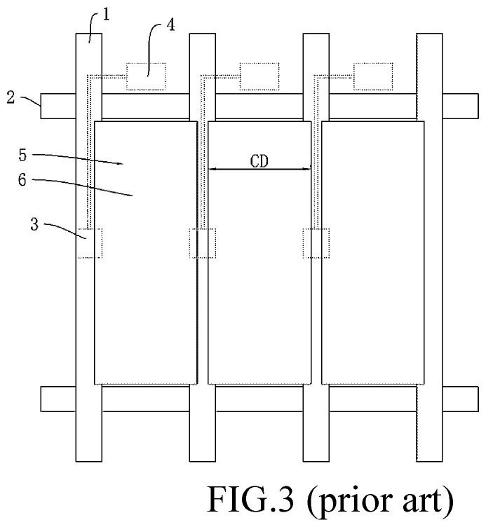

For implementing this application, please refer to FIG. 3. The current display panel includes a plurality of data signal lines 1 arranged in a vertical direction, a plurality of scan signal lines 2 arranged in a horizontal direction, and a plurality of sub-pixel areas 5 defined by the intersection of the data signal lines 1 and the scan signal lines 2. Each sub-pixel area 5 corresponds to a source electrode 3 and a drain electrode 4, wherein the source electrode 3 is electrically connected to the data signal line 1 to transmit a data signal to a corresponding sub-pixel area 5 through the drain electrode 4. Wherein, the data signal line 1, the source electrode 3, and the drain electrode 4 are all positioned in the same metal layer. The line width and line pitch of the lines formed by the current exposure equipment are about 1.5 μm, and a space should be reserved between the drain electrode 4, the source electrode 3, and the data signal line 1 to provide process space and reduce parasitic capacitance. Therefore, on the premise that the area of the display panel remains unchanged, it is difficult to effectively improve the resolution. However, please refer to FIG. 2, in the embodiment of the present application, the source electrode 31 and the data line 32 are arranged in the first metal layer 30, and the drain electrode 41 is arranged in the second metal layer 40, that is, the drain electrode 41 is arranged in a different layer from the source electrode 31 and the data line 32. This causes the first metal layer 30 and the second metal layer 40 to have more wiring space, reduces the difficulty of the process, and improves the resolution of the electronic device. In addition, each data line group 33 includes a plurality of data lines 32, where a distance between any two adjacent data line groups 33 is less than a distance between any two adjacent data lines 32 in any data line group 33. That is, at least the distance between two adjacent data line groups 33 is reduced, so more space for wiring can be reserved, and both the first metal layer 30 and the second metal layer 40 have more space for wiring, thereby improving the resolution of the electronic device.

Specifically, please refer to FIG. 1 and FIG. 2. The electronic device provided in this embodiment includes a display area 101 and a non-display area 102. The electronic device further includes a first substrate 10, a light-shielding layer 61 disposed on the first substrate 10, a first insulating layer 71 disposed on the first substrate 10 and covering the light-shielding layer 61, a semiconductor layer 20 disposed on the first insulating layer 71, a second insulating layer 72 disposed on the first insulating layer 71 and covering the semiconductor layer 20, a third metal layer 50 disposed on the second insulating layer 72, a third insulating layer 73 disposed on the second insulating layer 72 and covering the third metal layer 50, a first metal layer 30 disposed on the third insulating layer 73, a spacer layer 74 disposed on the third insulating layer 73 and covering the first metal layer 30, a second metal layer 40 disposed on the spacer layer 74, an interlayer dielectric layer 75 disposed on the spacer layer 74 and covering the second metal layer 40, a pixel electrode layer disposed on the interlayer dielectric layer 75, a passivation layer 76 disposed on the interlayer dielectric layer 75 and covering the pixel electrode layer, and a common electrode layer disposed on the passivation layer 76.

Optionally, the materials of the first insulating layer 71, the second insulating layer 72, the third insulating layer 73, the spacer layer 74, the interlayer dielectric layer 75, and the passivation layer 76 can all be organic insulating materials or inorganic insulating materials. For example, the organic insulating material can be polyimide, and the inorganic insulating material can be silicon nitride or silicon oxide, etc., which are not limited herein.

It should be noted that, in the above film layer structure, the semiconductor layer 20 includes a plurality of active parts 21 arranged in the display area 101. The third metal layer 50 includes a plurality of gate electrodes 51 and a plurality of scan lines 52 arranged in the display area 101, and a first connection portion 53 arranged in the non-display area 102. The first metal layer 30 includes a plurality of source electrodes 31 and a plurality of data lines 32 arranged in the display area 101. The second metal layer 40 includes a plurality of drain electrodes 41 arranged in the display area 101 and a second connection portion 42 arranged in the non-display area 102. The pixel electrode layer includes a pixel electrode 62 arranged in the display area 101 and a third connection portion 64 arranged in the non-display area 102. The common electrode layer includes a common electrode arranged in the display area 101 and a fourth connection portion 65 arranged in the non-display area 102.

Further, each active part 21 is positioned above a respective light-shielding layer 61, and a source electrode 31, a drain electrode 41, a gate electrode 51, and an active part 21 are corresponding to each other to constitute a thin film transistor element. Wherein, each active part 21 includes a source contact sub-portion 211, a drain contact sub-portion 212, and a channel sub-portion 213 positioned between the source contact sub-portion 211 and the drain contact sub-portion 212. Further, each source electrode 31 is electrically connected to the source contact sub-portion 211 of a respective active part 21, and each drain electrode 41 is electrically connected to a respective drain contact sub-portion 212 of an active part 21. Specifically, each source electrode 31 is electrically connected to a respective source contact sub-section 211 through a first via defined between the first metal layer 30 and the semiconductor layer 20. Each drain electrode is electrically connected to a respective drain contact sub-portion 212 through a second via defined between the second metal layer 40 and the semiconductor layer 20, and each gate electrode 51 is positioned above a respective active part 21.

In addition, a plurality of data lines 32 are arranged along a first direction X and extend along a second direction Y, and each source electrode 31 is electrically connected to a respective data line 32. Furthermore, each data line 32 transmits data signals through a respective source electrode 31, an active part 21 and a drain electrode 41 corresponding to the source electrode 31.

In the embodiment of the present application, the pixel electrode 62 is connected to the drain electrode 41 through a third via passing through the interlayer dielectric layer 75. Further, the drain electrode 41 can transmit the data signal in a corresponding data line 32 to the pixel electrode 62.

The passivation layer 76 conformally covers the third via, and the common electrode 63 also conformally covers the third via and can form an electric field with the pixel electrode 62. In addition, the electronic device further includes a filling portion 66 disposed in the third via to fill the third via and improve the flatness of the film layer.

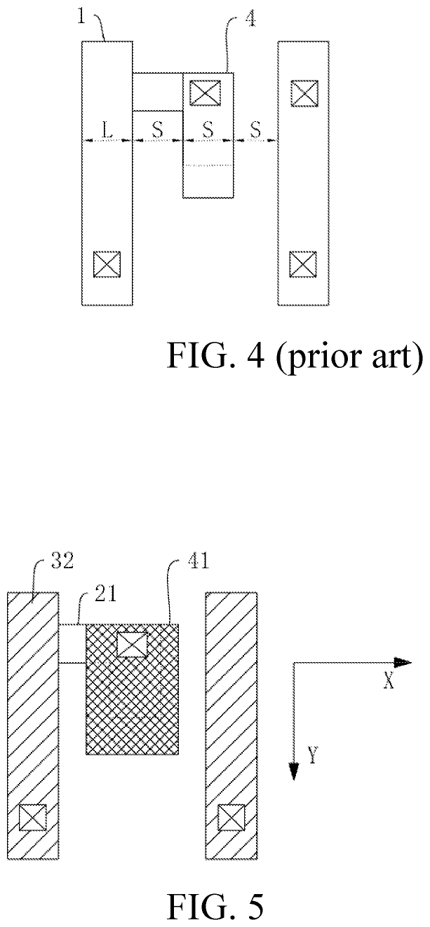

Please refer to FIG. 4, in the prior art, the drain electrode 4 is positioned between two adjacent data signal lines 1. The line width of the data signal line 1 is defined as L, and the line pitch is defined as L+3S. Due to the limitation of process capability and space limitation, both L and S have their limit values, and after reaching the limit values, L and S cannot be further reduced, thereby limiting the increase in the number of data signal lines 1 and the resolution of the electronic device. In addition, in the prior art, since the drain electrode 4 and the data signal line 1 are arranged in the same layer, if the line width and line pitch of the data signal line 1 are reduced to reach their limit to improve resolution, it is easy to cause the electrodes and signal lines in the same layer to be short-circuited or open-circuited, which seriously affects the yield of the electronic device.

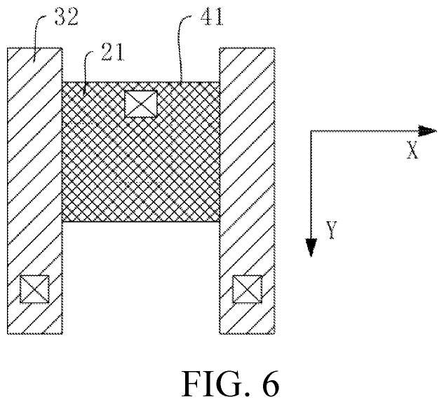

However, in the embodiment of the present application, please refer to FIG. 5 and FIG. 6, due to the drain electrode 41 and the data line 32 being positioned in different layers, the influence of the widths of the drain electrode 41 and the data line 32 and the spacing between the drain electrode 41 and the data line 32 do not need to be considered, that is, the width of the drain electrode 41 along the first direction X can be less than the distance between two adjacent data lines 32 as shown in FIG. 5, or equal to the distance between two adjacent data lines 32 as shown in FIG. 6. In the embodiment of the present application, the drain electrode 41 and the data line 32 are arranged in different layers, so that a large space can be reserved for wiring, which can improve the resolution while ensuring the yield of the electronic device.

Wherein, the first metal layer 30 includes a plurality of data line groups 33 arranged along the first direction X, and each data line group 33 includes a plurality of data lines 32. In this embodiment of the present application, the distance between adjacent data line groups 33 is less than the distance between any two adjacent data lines 32 in any of the data line groups 33. Further, in this embodiment, the orthographic projection of each drain electrode 41 on the first substrate 10 is positioned between the orthographic projections of the two adjacent data lines 32 in each data line group 33 on the first substrate 10, that is, there is no drain electrode 41 provided between two adjacent data line groups 33.

It should be noted that, due to the limitation of wiring space and process capability in the prior art, the width of the drain electrode along the horizontal direction is generally 1.5 μm. However, in the embodiment of the present application, the width of the drain electrode 41 along the first direction X can be greater than or equal to 2 μm.

Please continue to refer to FIG. 1 and FIG. 2, the electronic device provided by the embodiment of the present application further includes a plurality of pixel regions defined in the display area 101. Each pixel area includes a first sub-pixel area 1011, a second sub-pixel area 1012, and a third sub-pixel area 1013, wherein the second sub-pixel area 1012 is adjacent to the first sub-pixel area 1011 along the first direction X, and the third sub-pixel area 1013 is adjacent to the first sub-pixel area 1011 along the second direction Y. Wherein, each sub-pixel area is provided with a pixel electrode and a respective thin film transistor element, and each sub-pixel area is corresponding to a data line 32, that is, the corresponding data line 32 is electrically connected to the source electrode 31 corresponding to each sub-pixel area and transmits the data signal to the pixel electrode in the sub-pixel area through the corresponding active part 21 and the drain electrode 41.

In the embodiment of the present application, each data line group 33 corresponds to one sub-pixel area, that is, each data line group 33 includes a first data line 321, a second data line 322, and a third data line 323.

Further, each first sub-pixel area 1011 and each third sub-pixel area 1013 are positioned between the first data line 321 and the second data line 322. Each second sub-pixel area 1012 is positioned between the second data line 322 and the third data line 323.

Furthermore, in each data line group 33, the first data line 321, the second data line 322, and the third data line 323 are arranged in sequence along the first direction X, and the first data line in a data line group is adjacent to a third data line in an adjacent data line group, and is spaced from a third data line in another adjacent data line group, and is spaced from a first data line 321, two second data lines 322, and a third data line 323. Wherein, a distance between the adjacent first data line 321 and the third data line 323 in two adjacent data line groups 33 is less than a distance between the first data line 321 and the second data line 322 in any data line group 33, or is less than a distance between the second data line 322 and the third data line 323 in any data line group 33, and a distance between the first data line 321 and the second data line 322 in any data line group 33 is equal to a distance between the second data line 322 and the third data line 323 in any data line group 33.

Optionally, in one data line group 33, both the distance between the first data line 321 and the second data line 322 and the distance between the second data line 322 and the third data line 323 can be 5 μm, and the distance between the two adjacent data line groups 33 or between the adjacent first data line 321 and the third data line 323 can be 1.5 μm.

In the embodiment of the present application, the first data line 321 transmits the data line signal to the pixel electrode in the first sub-pixel area 1011 through the corresponding source electrode 31 and the active part 21 and the drain electrode 41 corresponding to the source electrode 31. The second data line 322 transmits the data line signal to the pixel electrode in the second sub-pixel region 1012 through the corresponding source electrode 31, the active part 21 and the drain electrode 41 corresponding to the source electrode 31. The third data line 323 transmits the data line signal to the pixel electrode in the third sub-pixel area 1013 through the corresponding source electrode 31, the active part 21 and the drain electrode 41 corresponding to the source electrode 31. The source electrodes 31 include a first source electrode 311 corresponding to the first data line 321, a second source electrode 312 corresponding to the second data line 322, and a third source electrode 313 corresponding to the third data line 323. The drain electrodes 41 include a first drain electrode 411 corresponding to the first data line 321, a second drain electrode 412 corresponding to the second data line 322, and a third drain electrode 413 corresponding to the third data line 323.

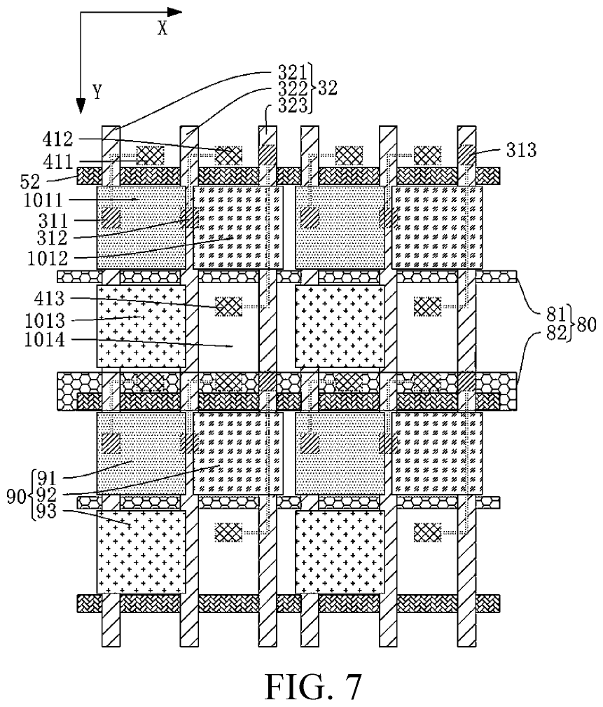

Please refer to FIG. 1, FIG. 2, and FIG. 7. The orthographic projections of the first source electrode 311, the second source electrode 312, and the third source electrode 313 on the first substrate 10 are all positioned within the coverage area of the orthographic projection of the data line 32 on the first substrate 10. In addition, the first drain electrode 411, the second drain electrode 412, and the first source electrode 311 corresponding to the same pixel area are arranged along the first direction and are positioned between two adjacent pixel areas arranged along the second direction Y.

In the embodiment of the present application, the scan lines 52 extend along the first direction X and are arranged along the second direction Y, and any scan line 52 is positioned between two adjacent pixel areas arranged along the second direction Y. That is, the first drain electrode 411, the second drain electrode 412, and the first source electrode 311 are positioned on the side of the scan line 52 away from the first substrate 10.

Optionally, the distance between two adjacent scan lines 52 along the second direction Y can be equal to 16 μm. In addition, each pixel area further includes a fourth sub-pixel area 1014 adjacent to the third sub-pixel area 1013 along the first direction X and adjacent to the second sub-pixel area 1012 along the second direction Y, and the third drain electrode 413 is arranged in the fourth sub-pixel area 1014.

The electronic device provided by the embodiment of the present application further includes a second substrate (not shown) disposed on the side of the first metal layer 30 and the second metal layer 40 away from the first substrate 10. In the embodiment of the present application, the second substrate is positioned on the side of the second metal layer 40 away from the first metal layer 30 as an example for description.

It should be noted that, in other embodiments of the present application, the second metal layer may also be arranged between the first metal layer and the semiconductor layer. The purpose is to arrange the drain electrode in a different layer from the data line and the source electrode to provide more space for wiring. Other arrangements, such as the distribution of sub-pixel areas, data lines, source electrodes, and drain electrodes, can be configured with reference to the embodiments of the present application, and details are not described herein.

In the embodiment of the present application, the electronic device further includes a black matrix layer 80 and a color resist layer 90 disposed on the side of the second substrate close to the first substrate 10, wherein the black matrix layer 80 is arranged around each sub-pixel area and is defined with a plurality of openings. The color resist layer 90 includes a plurality of color resist blocks, a sub-pixel area corresponds to an opening, and the opening corresponds to a color resist block, that is, the sub-pixel area corresponds to the color resist block.

The orthographic projection of the scan line 52 on the first substrate 10, the orthographic projection of the first drain electrode 411 on the first substrate 10, the orthographic projection of the second drain electrode 412 on the first substrate 10, and the orthographic projection of the third source electrode 313 on the first substrate 10 are positioned within the coverage area of the orthographic projection of the black matrix layer 80 on the first substrate 10.

Specifically, the black matrix layer 80 includes a first sub-portion 81 disposed between the first sub-pixel area 1011 and the third sub-pixel area 1013 and is positioned between two adjacent scan lines 52 and a second sub-portion 82 disposed between two adjacent pixel areas along the second direction Y, wherein the length of the first sub-portion 81 along the second direction Y is less than the length of the second sub-portion 82 along the second direction Y. The orthographic projection of the scan line 52 on the first substrate 10, the orthographic projection of the first drain electrode 411 on the first substrate 10, the orthographic projection of the second drain electrode 412 on the first substrate 10, and the orthographic projection of the third source electrode 313 on the first substrate 10 are all positioned within the coverage area of the orthographic projection of the second sub-portion 82 on the first substrate 10.

It can be understood that, in the embodiments of the present application, only parts of the black matrix layer 80 are shown, for example, the first sub-portion 81 and the second sub-portion 82. The black matrix layer 80 further includes other parts, which are arranged around each sub-pixel area to prevent the phenomenon of cross-color between adjacent sub-pixel areas.

In addition, the color resist blocks include first color resist blocks 91, second color resist blocks 92, and third color resist blocks 93, wherein a first color resist block 91 is correspondingly arranged in a first sub-pixel area 1011 and partially overlaps with the adjacent first data line 321 and the second data line 322, a second color resist block 92 is correspondingly arranged in a second sub-pixel area 1012 and partially overlaps with the adjacent second data line 322 and the third data line 323, and a third color resist block 93 is correspondingly arranged in a third sub-pixel area 1013 and partially overlaps with the adjacent first data line 321 and the second data line 322.

Optionally, the first color resist block 91 can be a red color resist block, the second color resist block 92 can be a green color resist block, and the third color resist block 93 can be a blue color resist block.

Further, the length of the overlapping portion of the first color resist block 91 and the first data line 321 along the first direction X is equal to the width of the first data line 321 along the first direction X, the length of the overlapping portion of the first color resist block 91 and the second data line 322 along the first direction X is less than the width of the second data line 322 along the first direction X; the length of the overlapping portion of the second color resist block 92 and the second data line 322 along the first direction X is less than the width of the second data line 322 along the first direction X, and the length of the overlapping portion of the second color resist block 92 and the third data line 323 along the first direction X is equal to the width of the third data line 323 along the first direction X. The length of the overlapping portion of the third color resist block 93 and the first data line 321 along the first direction X is equal to the width of the first data line 321 along the first direction X, and the length of the overlapping portion of the third color resist block 93 and the second data line 322 along the first direction X is less than or equal to the width of the second data line 322 along the first direction X.

Optionally, the width of the first color resist block 91 along the first direction X, the width of the second color resist block 92 along the first direction X, and the width of the third color resist block 93 along the first direction X may all be equal to 8 μm.

Optionally, the third color resist block 93 may also be arranged in the third sub-pixel area 1013 and partially extend into the fourth sub-pixel area 1014.

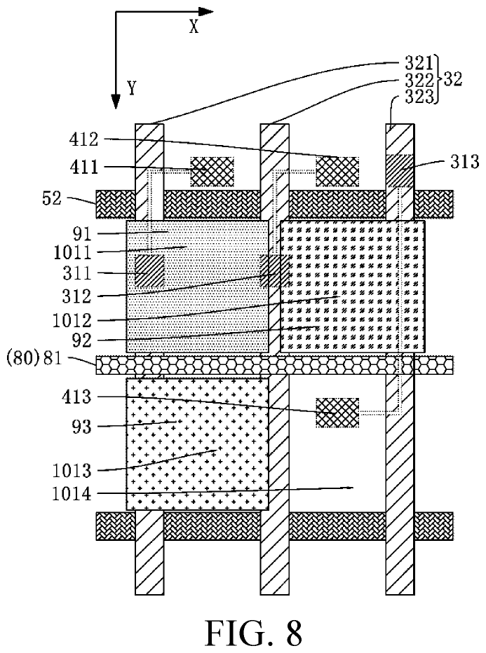

Please refer to FIG. 3, in the prior art, the display panel includes a color resist block 6 arranged in the sub-pixel area 5. According to current process capability, the maximum CD value of the color resist block 6 can be designed to be 5.6 μm, but because it is necessary to prevent the phenomenon of cross-color between adjacent color resist block 6, the actual CD value needs to be less than 5.6 μm. This increases the distance between adjacent color resist block 6, and thus it is difficult to increase the number of color resist block 6 by reducing the CD value of the color resist block 6 to improve the resolution of the display panel. In addition, the reduction of the CD value of the color resist block 6 cannot exceed the limitation of the current process capability. However, referring to FIG. 7 and FIG. 8, in the embodiment of the present application, the arrangement of color resist blocks is changed from three color resist blocks 6 a row in each pixel area in the prior art to two color resist blocks (i.e. first color resist block 91 and second color resist block 92) a row in each pixel area in this embodiment, the third color resist block 93 is moved to the other side of the first color resist block 91, and the length of each color resist block is reduced along the second direction Y. In this way, the width and arrangement space of each color resist block along the first direction X can be increased, thereby reducing the manufacturing difficulty of each color resist block, and effectively improving the resolution of the electronic device.

In the embodiment of the present application, the distance from the end of the first sub-portion 81 away from the adjacent second sub-portion 82 to the end of the second sub-portion 82 away from the adjacent first sub-portion 81 is defined as first distance, and the length of each color resist block along the second direction Y can be less than or equal to the first distance. That is, the length of the first color resist block 91 along the second direction Y, the length of the second color resist block 92 along the second direction Y, and the length of the third color resist block 93 along the second direction Y can all be less than or equal to the first distance.

The electronic device provided in the embodiment of the present application can also be applied to the field of virtual reality (VR) display, which can effectively improve the resolution and display effect of the VR device. It should be noted that when the electronic device provided in the embodiment of the present application is used in the field of VR display, due to the small space, the thin film transistor element in the embodiment of the present application includes a source electrode 31, a drain electrode 41, an active portion 21, and a gate electrode 51, that is, a single-gate structure. In addition, the thickness of the gate electrode 51 can be thickened to adjust the electrical properties of the thin film transistor elements, which can be selected according to actual needs.

As described above, in the present application, the source electrodes 31 and the data lines 32 are arranged in the first metal layer 30, and the drain electrodes 41 are arranged in the second metal layer 40, that is, the drain electrodes 41 are arranged in a different layer from the source electrodes 31 and the data lines 32. Therefore, the space required for wiring can be increased. Furthermore, each data line group 33 includes a plurality of data lines 32, and a distance between any two adjacent data line groups 33 is less than a distance between any two adjacent data lines 32 in any data line group 33, that is, at least the distance between two adjacent data line groups 33 is reduced, more space for wiring can be reserved, so that both the first metal layer 30 and the second metal layer 40 have more space for wiring. In addition, the arrangement of the sub-pixel areas has also been newly designed, which can reserve enough space for each color resist block, reduce the process difficulty of the color resist block, and effectively improve the resolution of electronic device.

In the above-mentioned embodiments, the description of each embodiment has its own emphasis. For parts that are not described in detail in a certain embodiment, reference may be made to the relevant descriptions of other embodiments.

The electronic device provided by the embodiments of the present application has been described in detail above. The principles and implementations of the present application are described herein using specific examples, and the descriptions of the above embodiments are only used to help understand the technical solutions and core ideas of the present application. One ordinary skill in the art should understand that it is still possible to modify the technical solutions recorded in the foregoing embodiments or perform equivalent replacements to some of the technical features. These modifications or replacements do not make the essence of the corresponding technical solutions deviate from the scope of the technical solutions in the embodiments of the present application.

What is claimed is:

1. An electronic device, comprising:
a first substrate;
a semiconductor layer disposed on a side of the first substrate, wherein the semiconductor layer comprises active parts, and each active part comprises a source contact sub-portion, a drain contact sub-portion, and a channel sub-portion positioned between the source contact sub-portion and the drain contact sub-portion;
a first metal layer disposed on a side of the semiconductor layer away from the first substrate and comprising source electrodes and data lines, wherein one end of one of the source electrodes is electrically connected to a respective one of the data lines, and another end of the source electrode is electrically connected to the source contact sub-portion of the active part; and
a second metal layer disposed on the side of the semiconductor layer away from the first substrate and is positioned in a different layer from the first metal layer, wherein the second metal layer comprises drain electrodes, one of the drain electrodes is electrically connected to the drain contact sub-portion of one of the active parts;
wherein the first metal layer comprises data line groups, each data line group comprises a plurality of the data lines, and wherein a distance between any two adjacent data line groups is less than a distance between any two adjacent data lines in any of the data line groups.

2. The electronic device of claim 1, wherein the second metal layer is disposed on a side of the first metal layer away from the semiconductor layer, and the electronic device further comprises a spacer layer disposed between the first metal layer and the second metal layer.

3. The electronic device of claim 1, wherein the data lines are arranged along a first direction and extend along a second direction, the first direction is different from the second direction, and wherein an orthographic projection of the drain electrode on the first substrate is positioned between orthographic projections of two adjacent data lines in one of the data line groups on the first substrate.

4. The electronic device of claim 3, wherein a width of the drain electrode along the first direction is greater than or equal to 2 μm.

5. The electronic device of claim 3, wherein a width of the drain electrode along the first direction is less than or equal to a spacing between the two adjacent data lines in the data line group.

6. The electronic device of claim 3, further comprising pixel areas, wherein one of the pixel areas corresponds to one of the data line groups, and each pixel area comprises one of first sub-pixel areas, one of second sub-pixel areas adjacent to the first sub-pixel area along the first direction, and one of third sub-pixel areas adjacent to the first sub-pixel area along the second direction; and
wherein each data line group comprises a first data line, a second data line, and a third data line, the first sub-pixel area and the third sub-pixel area in the pixel area are positioned between the first data line and the second data line in the data line group, and the second sub-pixel area in the pixel area is positioned between the second data line and the third data line in the data line group.

7. The electronic device of claim 6, wherein the first data line in one of the data line groups is adjacent to the third data line in an adjacent one of the data line groups, and
wherein a distance between two adjacent first data line and third data line in two adjacent data line groups is less than a distance between the first data line and the second data line in the data line group, or less than a distance between the second data line and the third data line in the data line group.

8. The electronic device of claim 6, further comprising a second substrate disposed on a side of the first metal layer and the second metal layer away from the first substrate, and a color resist layer disposed on a side of the second substrate close to the first substrate, wherein the color resist layer comprises first color resist blocks, second color resist blocks, and third color resist blocks disposed corresponding to each of the pixel areas; and
wherein one of the first color resist blocks is correspondingly disposed in one of the first sub-pixel areas and partially overlaps with adjacent first data line and second data line, one of the second color resist blocks is correspondingly disposed in one of the second sub-pixel areas and partially overlaps with adjacent second data line and third data line, and one of the third color resist blocks is correspondingly disposed in one of the third sub-pixel areas and partially overlaps with adjacent first data line and second data line.

9. The electronic device of claim 8, wherein a length of an overlapping portion of the first color resist block and the first data line along the first direction is equal to a width of the first data line along the first direction, and a length of an overlapping portion of the first color resist block and the second data line along the first direction is less than a width of the second data line along the first direction;
wherein a length of an overlapping portion of the second color resist block and the second data line along the first direction is less than a width of the second data line along the first direction, and a length of an overlapping portion of the second color resist block and the third data line along the first direction is equal to a width of the third data line along the first direction; and
wherein a length of an overlapping portion of the third color resist block and the first data line along the first direction is equal to a width of the first data line along the first direction, and a length of an overlapping portion of the third color resist block and the second data line along the first direction is less than or equal to a width of the second data line along the first direction.

10. The electronic device of claim 8, wherein each pixel area further comprises a fourth sub-pixel area adjacent to the third sub-pixel area in the first direction and adjacent to the second sub-pixel area in the second direction, and the third color resist block is disposed in the third sub-pixel area and partially extends to the fourth sub-pixel area.

11. The electronic device of claim 10, wherein each source electrode is connected to a respective one of the data lines and is connected to a respective one of the drain electrodes through a respective one of the active parts, wherein the drain electrodes comprise a first drain electrode corresponding to the first data line, and in each pixel area, the first drain electrode is disposed in the fourth sub-pixel area.

12. The electronic device of claim 11, wherein the drain electrodes further comprise a second drain corresponding to the second data line, the source electrodes comprise a third source electrode corresponding to the third data line, and the first drain electrode, the second drain electrode, and the third source electrode are arranged along the first direction and positioned between two adjacent pixel areas along the second direction.

13. The electronic device of claim 12, further comprising a third metal layer disposed on a side of the first metal layer and the second metal layer close to the semiconductor layer, wherein the third metal layer comprises scan lines extending along the first direction and arranged along the second direction, each scan line is positioned between two adjacent pixel areas arranged along the second direction, and the first drain electrode, the second drain electrode, and the third source electrode are all positioned on a side of the scan lines away from the first substrate.

14. The electronic device of claim 13, further comprising a black matrix layer disposed on the side of the second substrate close to the first substrate, wherein the black matrix layer is arranged around the first sub-pixel area, the second sub-pixel area, and the third sub-pixel area; and
wherein an orthographic projection of the scan line on the first substrate, an orthographic projection of the first drain electrode on the first substrate, an orthographic projection of the second drain electrode on the first substrate, and an orthographic projection of the third source electrode on the first substrate are all positioned within a coverage range of an orthographic projection of the black matrix layer on the first substrate.

15. The electronic device of claim 14, wherein the black matrix layer comprises a first sub-portion disposed between the first sub-pixel area and the third sub-pixel area and between two adjacent scan lines and a second sub-portion disposed between two adjacent pixel areas along the second direction, wherein a length of the first sub-portion along the second direction is less than a length of the second sub-portion along the second direction; and
wherein an orthographic projection of the scan line on the first substrate, an orthographic projection of the first drain electrode on the first substrate, an orthographic projection of the second drain electrode on the first substrate, and an orthographic projection of the third source electrode on the first substrate are all positioned within a coverage range of an orthographic projection of the second sub-portion on the first substrate.
